(19) United States
(12) Patent Application Publication
(10) Pub. No.: US 2023/0389427 A1
(43) Pub. Date: Nov. 30, 2023

(54) THERMOELECTRIC MODULE

(71) Applicant: KELK Ltd., Kanagawa (JP)

(72) Inventors: Takaaki OHTA, Hiratsuka-shi (JP); Tetsushi TANAKA, Hiratsuka-shi (JP)

(21) Appl. No.: 18/320,329

(22) Filed: May 19, 2023

(30) Foreign Application Priority Data
May 30, 2022 (JP) 2022-087818

(51) Int. Cl. H10N 10/17; H10N 10/01

(52) U.S. Cl. CPC H10N 10/17; H10N 10/01

(57) ABSTRACT

A thermoelectric module for optical communication includes a first substrate and a second substrate that are a pair of substrates disposed opposite to each other, a plurality of thermoelectric conversion elements disposed between the first substrate and the second substrate, a first electrode and a second electrode that are a pair of electrodes connecting the thermoelectric conversion elements, a metallized portion disposed on the second substrate, a post electrode, of an anode, electrically connected to the first electrode and the second electrode, a post electrode, of a cathode, electrically connected to the first electrode and the second electrode, and a wire as a conductor structure electrically connecting the metallized portion and a part having a lower voltage than the post electrode of the anode.

### CROSS-REFERENCE TO RELATED APPLICATION(S)

The present application claims priority to and incorporates by reference the entire contents of Japanese Patent Application No. 2022-087818 filed in Japan on May 30, 2022.

### BACKGROUND OF THE INVENTION

### 1. Field of the Invention

The present disclosure relates to a thermoelectric module.

### 2. Description of the Related Art

Performance of thermoelectric modules deteriorate if Cu and Ni, which serve as thermoelectric elements and electrode materials of thermoelectric modules, cause electrochemical migration during operation under a condensation condition. Concerning a thermoelectric module, a technique is known that includes forming a film of an insulating material on a surface of a thermoelectric element excluding a joint surface with an electrode (see, for example, JP 2021-097186 A). In order to prevent electrochemical migration of Cu in an inner lead of a semiconductor device, a technique of sealing with a resin is known (see, for example, JP 2003-092379 A).

In JP 2021-097186 A, no film is formed on a cooling surface and a post electrode of the thermoelectric module. Therefore, in a case where a metallized portion is disposed on the cooling surface, the metallized portion may come into contact with an anode and a cathode as the post electrodes via water generated on the cooling surface. At this time, the metallized portion has a potential between the potential of the anode and the potential of the cathode, and therefore a current flows through the metallized portion via water, and a metal such as Cu or Ni as a material of the metallized portion may cause electrochemical migration. As a result, a decrease in thermal conductivity and a decrease in joint strength occur in the metallized portion.

When the sealing with a resin described in JP 2003-092379 A is applied to a metallized portion on a cooling surface and a post electrode in a thermoelectric module, the cooling performance deteriorates due to heat conduction by the resin.

An object of the present disclosure is to suppress deterioration of cooling performance and to suppress electrochemical migration.

### SUMMARY OF THE INVENTION

It is an object of the present invention to at least partially solve the problems in the conventional technology.

According to an aspect of the present invention, a thermoelectric module to be used for optical communication, the thermoelectric module comprises: a pair of substrates disposed opposite to each other; a plurality of thermoelectric elements disposed between the pair of substrates; a pair of electrodes connecting the plurality of thermoelectric elements; a metallized portion disposed on one substrate of the pair of substrates; an anode electrode electrically connected to the pair of electrodes; a cathode electrode electrically connected to the pair of electrodes; and a conductor structure electrically connecting the metallized portion and a part having a lower voltage than the anode electrode.

According to another aspect of the present invention, a thermoelectric module to be used for optical communication, the thermoelectric module comprises: a pair of substrates disposed opposite to each other; a plurality of thermoelectric elements disposed between the pair of substrates; a pair of electrodes connecting the plurality of thermoelectric elements; a metallized portion disposed on one substrate of the pair of substrates; an anode electrode electrically connected to the pair of electrodes; a cathode electrode electrically connected to the pair of electrodes; and a waterproof member disposed in a state where the metallized portion, the anode electrode, and the cathode electrode are separated from each other.

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIG. 1 is a plan view schematically illustrating a thermoelectric module according to a first embodiment;

FIG. 2 is a sectional view schematically illustrating the thermoelectric module according to the first embodiment;

FIG. 3 is a plan view schematically illustrating a modification of the thermoelectric module according to the first embodiment;

FIG. 4 is a sectional view schematically illustrating a modification of the thermoelectric module according to the first embodiment;

FIG. 5 is a plan view schematically illustrating a modification of the thermoelectric module according to the first embodiment;

FIG. 6A is a sectional view schematically illustrating a modification of the thermoelectric module according to the first embodiment;

FIG. 6B is a sectional view schematically illustrating a modification of the thermoelectric module according to the first embodiment;

FIG. 7 is a plan view schematically illustrating a modification of the thermoelectric module according to the first embodiment;

FIG. 8 is a sectional view schematically illustrating a modification of the thermoelectric module according to the first embodiment;

FIG. 9 is a plan view schematically illustrating a thermoelectric module according to a second embodiment;

FIG. 10 is a sectional view schematically illustrating the thermoelectric module according to the second embodiment;

FIG. 11 is a plan view schematically illustrating a modification of the thermoelectric module according to the second embodiment;

FIG. 12 is a sectional view schematically illustrating a modification of the thermoelectric module according to the second embodiment;

FIG. 13 is a plan view schematically illustrating a modification of the thermoelectric module according to the second embodiment;

FIG. 14 is a sectional view schematically illustrating a modification of the thermoelectric module according to the second embodiment;

FIG. 15 is a plan view schematically illustrating a modification of the thermoelectric module according to the second embodiment;

FIG. 16 is a sectional view schematically illustrating a modification of the thermoelectric module according to the second embodiment;

FIG. 17 is a plan view schematically illustrating a thermoelectric module with a housing, according to a third embodiment;

FIG. 18 is a sectional view schematically illustrating the thermoelectric module with a housing, according to the third embodiment;

FIG. 19 is a plan view schematically illustrating the upper surface of the thermoelectric module according to the third embodiment;

FIG. 20 is a plan view schematically illustrating the lower surface of the thermoelectric module according to the third embodiment;

FIG. 21 is a sectional view schematically illustrating the thermoelectric module according to the third embodiment;

FIG. 22 is a plan view schematically illustrating the housing according to the third embodiment; and

FIG. 23 is a sectional view schematically illustrating the housing according to the third embodiment.

### DETAILED DESCRIPTION OF THE PREFERRED EMBODIMENTS

Hereinafter, embodiments according to the present disclosure will be described with reference to the drawings, but the present disclosure is not limited to the embodiments. Constituent elements of a plurality of embodiments described below can be appropriately combined. Some constituent elements may be not used.

In an embodiment, terms “left”, “right”, “front”, “rear”, “upper”, and “lower” are used to describe the positional relationship among portions. These terms indicate relative positions or relative directions with respect to the center of an optical communication apparatus 1. The left-right direction, the front-rear direction, and the upper-lower direction are orthogonal to each other.

### First Embodiment

Thermoelectric Module

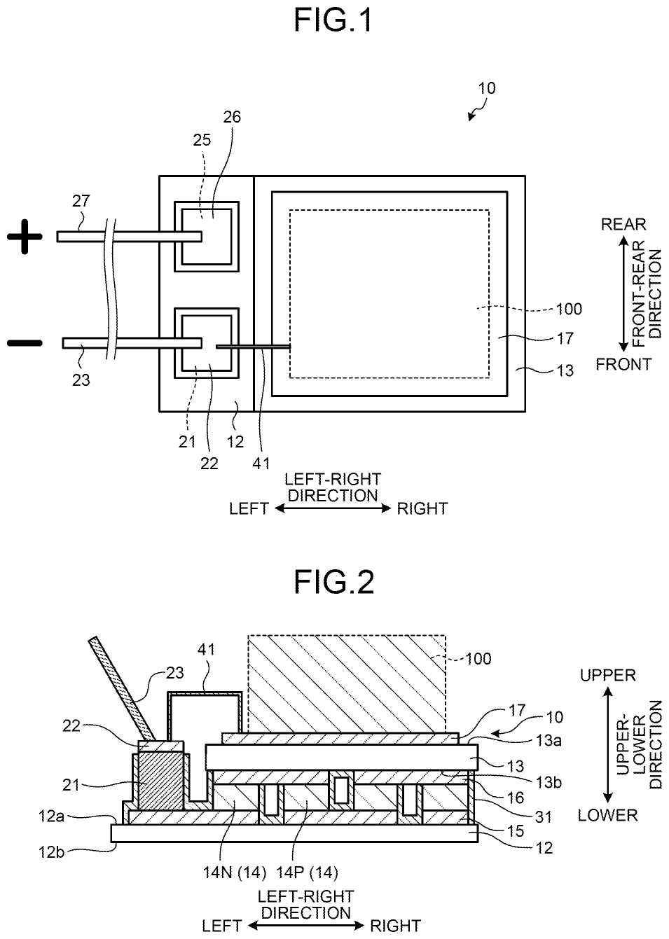

FIG. 1 is a plan view schematically illustrating a thermoelectric module according to a first embodiment.

FIG. 2 is a sectional view schematically illustrating the thermoelectric module according to the first embodiment. A thermoelectric module 10 performs, for example, temperature control of an optical component 100 to be used for optical communication. The thermoelectric module 10 supports the optical component 100. As illustrated in FIG. 2, the thermoelectric module 10 includes a first substrate 12 and a second substrate 13 that are a pair of substrates, and a thermoelectric conversion element (thermoelectric element) 14 disposed between the first substrate 12 and the second substrate 13. The disposition of the thermoelectric conversion element 14, a first electrode 15, and a second electrode 16 in each drawing used in the following description is schematically illustrated.

In the thermoelectric module 10, the first substrate 12 and the second substrate 13 have different areas. In the thermoelectric module 10 in an embodiment, the second substrate 13 is smaller than the first substrate 12 in the width direction or the entire circumference.

The pair of the first substrate 12 and the second substrate 13 are formed using an electrically insulating material. The first substrate 12 and the second substrate 13 include, for example, aluminum oxide (Al₂O₃), zirconium oxide (ZrO₂), silicon dioxide, titanium oxide, silicon nitride (Si₃N₄), or aluminum nitride (AlN).

As illustrated in FIG. 1 and FIG. 2, the first substrate 12 and the second substrate 13 are disposed, as a pair, opposite to each other with the thermoelectric conversion element 14 interposed therebetween. In an embodiment, the second substrate 13 is disposed above the first substrate 12. The first substrate 12 and the second substrate 13 are formed into a plate shape. In an embodiment, the first substrate 12 and the second substrate 13 are formed into a rectangular shape. The second substrate 13 is one substrate, and the first substrate 12 is another substrate.

As illustrated in FIG. 2, one or more thermoelectric conversion elements 14 are disposed between the pair of the first substrate 12 and the second substrate 13 opposite to each other. The plurality of thermoelectric conversion elements 14 are connected by a plurality of the first electrodes 15 and a plurality of the second electrodes 16.

Each thermoelectric conversion element 14 is formed using a thermoelectric material. Examples of the thermoelectric material forming the thermoelectric conversion element 14 include a manganese silicide-based compound (Mn—Si), a magnesium silicide-based compound (Mg—Si—Sn), a skutterudite-based compound (Co—Sb), a half-Heusler compound (Zr—Ni—Sn), and a bismuth telluride-based compound (Bi—Te). The thermoelectric conversion element 14 may include 1 compound selected from a manganese silicide-based compound, a magnesium silicide-based compound, a skutterudite-based compound, a half-Heusler compound, and a bismuth telluride-based compound, or may include a combination of at least 2 compounds.

The thermoelectric conversion element 14 includes a p-type element 14P and an n-type element 14N. A plurality of p-type elements 14P and a plurality of n-type elements 14N are disposed in a predetermined plane. The p-type elements 14P and the n-type elements 14N are alternately disposed in the front-rear direction. The p-type elements 14P and the n-type elements 14N are alternately disposed in the left-right direction.

A pair of the first electrode 15 and the second electrode 16 are formed using a conductive metal. The second electrode 16 is one substrate, and the first electrode 15 is another substrate. The first electrode 15 and the second electrode 16 are formed to include, for example, 3 layers of Cu, Ni, and Au. The first electrode is disposed between the first substrate 12 and the thermoelectric conversion element 14. The first electrodes and the second electrodes 16 connect the thermoelectric conversion elements 14. The first electrode 15 is provided on an upper surface 12a of the first substrate 12. A plurality of the first electrodes 15 are provided in a predetermined plane parallel to the upper surface 12a of the first substrate 12. The second electrode 16 is disposed between the second substrate 13 and the thermoelectric conversion element 14. The second electrode 16 is provided on a lower surface 13b of the second substrate 13. A plurality of the second electrodes 16 are provided in a predetermined plane parallel to the lower surface 13b of the second substrate 13.

The first electrode 15 and the second electrode 16 are each connected to a pair of a p-type element 14P and an n-type element 14N that are adjacent. The first electrodes 15 and the second electrodes 16 connect the plurality of thermoelectric conversion elements 14 in series. The first electrodes 15 and the second electrodes 16 form a series circuit in which the plurality of thermoelectric conversion elements 14 are connected in series. The p-type element 14P and the n-type element 14N are electrically connected via the first electrode 15 and the second electrode 16 to configure a pn element pair. A plurality of the pn element pairs are connected in series via the first electrodes 15 and the second electrodes 16 to configure a series circuit including the plurality of thermoelectric conversion elements 14.

A metallized portion 17 is disposed on an upper surface 13a of the second substrate 13. The metallized portion 17 fixes the optical component 100 to the upper surface 13a of the second substrate 13. The metallized portion 17 is formed using a conductive metal.

When a current is supplied to the thermoelectric conversion element 14, the thermoelectric module 10 absorbs or generates heat by the Peltier effect. This effect is used for temperature control of the optical component 100 disposed on the thermoelectric module 10.

A lower surface 12b of the first substrate 12 is a heat radiation surface of the thermoelectric module 10. The upper surface 13a of the second substrate 13 is a cooling surface (temperature control surface) of the thermoelectric module 10.

The thermoelectric module 10 includes a post 21 as a cathode, a post electrode 22, and a power supply wire 23. The post 21 is disposed on the first substrate 12. The post 21 is electrically connected to the first substrate 12. In the example illustrated in FIG. 1, the post 21 is provided in a left front side of the first substrate 12. The post 21 has a columnar shape. The post 21 is formed, for example, using Ni. The post electrode 22 as a cathode electrode is disposed on the upper end of the post 21. The post electrode 22 is electrically connected to a pair of the first electrode 15 and the second electrode 16. The post electrode 22 is electrically connected to the post 21. The post electrode 22 is formed, for example, using Au.

The thermoelectric module 10 includes a post 25 as an anode, a post electrode 26, and a power supply wire 27. The post 25 is electrically connected to the first substrate 12. The post 25 is disposed away from the post 21. In the example illustrated in FIG. 1, the post 25 is provided in a left rear side of the first substrate 12. The post 25 has a columnar shape. The post 25 is formed, for example, using Ni. The post electrode 26 as an anode electrode is disposed on the upper end of the post 25. The post electrode 26 is electrically connected to a pair of the first electrode 15 and the second electrode 16. The post electrode 26 is electrically connected to the post 25. The post electrode 26 is formed, for example, using Au.

The thermoelectric module 10 is covered with an insulating film 31. The insulating film 31 covers a part in the surface of the thermoelectric module 10 excluding a part lower than the first substrate 12 in the upper-lower direction, a part higher than the second substrate 13 in the upper-lower direction, the post electrode 22, and the post electrode 26. The insulating film 31 is formed using a material having an electrical insulation property. Examples of the material having an electrical insulation property include polyimides, polyparaxylylene, polytetrafluoroethylene, silicon dioxide, aluminum oxide, and titanium oxide. In FIG. 1, the insulating film 31 is not illustrated. The same applies to other plan views.

The thermoelectric module 10 prevents a current from flowing between the post electrode 22, the post electrode 26, and the metallized portion 17 via water attached to surfaces of the post electrode 22, the post electrode 26, and the metallized portion 17.

Cu and Ni, which are materials of the thermoelectric conversion elements 14 and the electrodes in the thermoelectric module 10, cause electrochemical migration during operation of the second substrate 13 under a condensation condition. The cause of the electrochemical migration is a current flowing out of the metallized portion 17 via water attached to the surface of the metallized portion 17. Therefore, the metallized portion 17 is wired to make a current flow in the wire, and thus electrochemical migration is prevented.

In an embodiment, in order to take a countermeasure against electrochemical migration, an elongated wire is provided that electrically connects the metallized portion 17 disposed on the upper surface 13a of the second substrate 13 and a place having a lower voltage than the post electrode 26 of the anode, for example, the post electrode 22 of the cathode. More specifically, the thermoelectric module 10 prevents a current from flowing between the post electrode 22 or the post electrode 26 and the metallized portion 17 via water attached to the surface of the metallized portion 17.

In the example illustrated in FIG. 1 and FIG. 2, the thermoelectric module 10 includes a wire 41 as a conductor structure that electrically connects the metallized portion 17 and a part having a lower voltage than the post electrode 26 of the anode. The wire 41 electrically connects the post electrode 22 of the cathode and the metallized portion 17. The wire 41 has conductivity and corrosion resistance. The wire 41 is formed, for example, using Au. The wire 41 may be formed, for example, using Ag, Pt, Pd, Cu, Ti, W, Ni, BiTe, or a combination of these materials. The wire 41 has an elongated shape. The wire 41 has, for example, a diameter of 25 μm and a length of 0.5 mm.

### Operation

In the thermoelectric module 10 in an embodiment, even if the metallized portion 17 has a potential under a condensation condition of the second substrate 13, a current flows through the wire 41 from the metallized portion 17 to the post electrode 22 of the cathode. In the thermoelectric module 10 in an embodiment, even under a condensation condition of the second substrate 13, generation of a potential in the metallized portion 17 is prevented by the wire 41. In the thermoelectric module 10 in an embodiment, even under a condensation condition of the second substrate 13, a current is prevented, by the wire 41, from flowing through the metallized portion 17 via water. Thus, in such an embodiment, electrochemical migration in the metallized portion 17 is prevented by the wire 41.

### Effect

In an embodiment, even if the metallized portion 17 has a potential under a condensation condition of the second substrate 13, the thermoelectric module 10 can make a current flow through the wire 41 from the metallized portion 17 to the post electrode 22 of the cathode. In an embodiment, even under a condensation condition of the second substrate 13, the thermoelectric module 10 can prevent, by the wire 41, generation of a potential in the metallized portion 17. According to an embodiment, even under a condensation condition of the second substrate 13, the thermoelectric module 10 can prevent, by the wire 41, a current from flowing through the metallized portion 17 via water. Thus, in such an embodiment, electrochemical migration in the metallized portion 17 can be prevented by the wire 41.

In an embodiment, the wire 41 is elongated. Such an embodiment can suppress deterioration of cooling performance caused by heat inflow to the metallized portion 17 or heat outflow from the metallized portion 17 via the wire 41.

### First Modification of First Embodiment

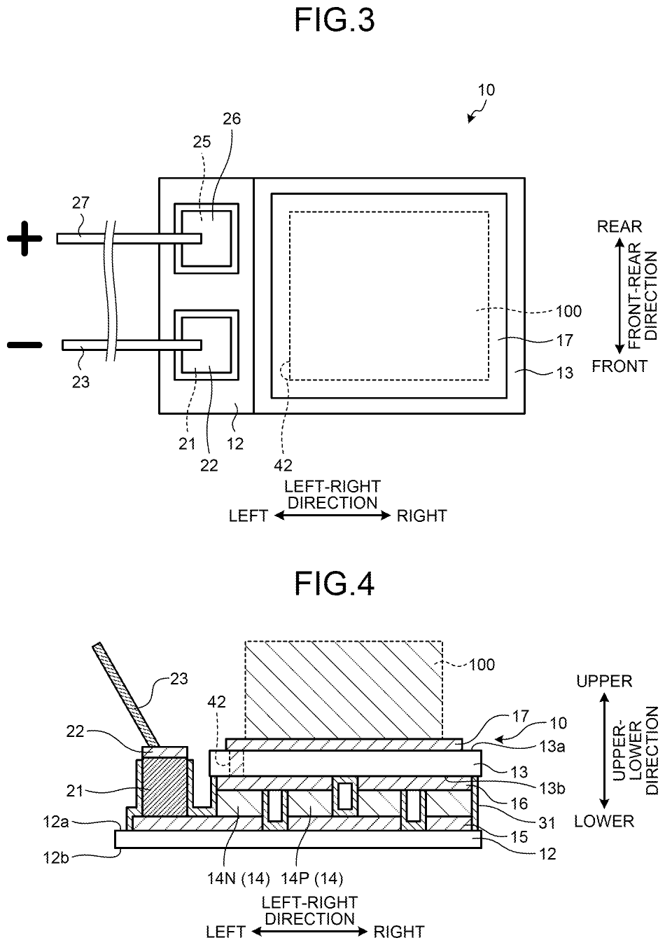

FIG. 3 is a plan view schematically illustrating a modification of the thermoelectric module according to the first embodiment. FIG. 4 is a sectional view schematically illustrating a modification of the thermoelectric module according to the first embodiment. The thermoelectric module 10 in the first modification has a basic configuration similar to that in the first embodiment. The configuration similar to that in the first embodiment is illustrated with the same reference numerals as those in the first embodiment, and description of the configuration will be omitted. The same applies to the following description of other modifications and other embodiments.

A thermoelectric module 10 includes a through hole 42 as a conductor structure. The through hole 42 electrically connects a metallized portion 17 and a second electrode 16. The through hole 42 is formed, for example, using Cu, Ni, Pd, or Au. The through hole 42 may be formed, for example, using Ag, Pt, Ti, W, BiTe, or a combination of these materials. The through hole 42 has an elongated shape.

In a modification, under a condensation condition of a second substrate 13, the thermoelectric module 10 can make a current flow through the through hole 42 from the metallized portion 17 to the second electrode 16. In a modification, even under a condensation condition of the second substrate 13, the thermoelectric module 10 can prevent, by the through hole 42, generation of a potential in the metallized portion 17. According to a modification, even under a condensation condition of the second substrate 13, the thermoelectric module 10 can prevent, by the through hole 42, a current from flowing through the metallized portion 17 via water. According to such a modification, electrochemical migration in the metallized portion 17 can be prevented by the through hole 42.

### Second Modification of First Embodiment

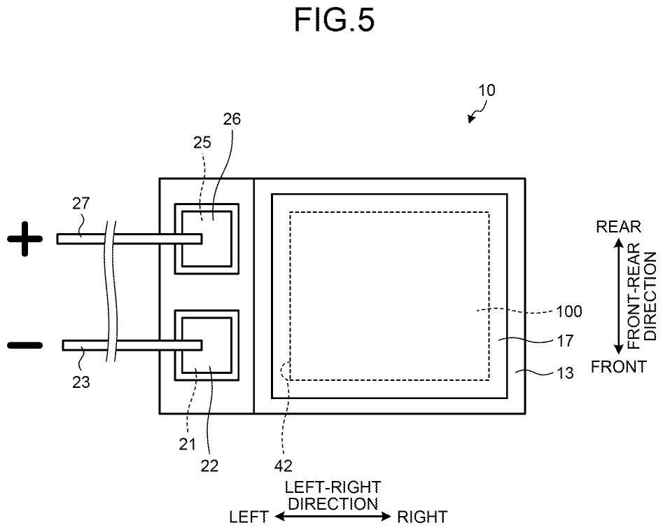

FIG. 5 is a plan view schematically illustrating a modification of the thermoelectric module according to the first embodiment.

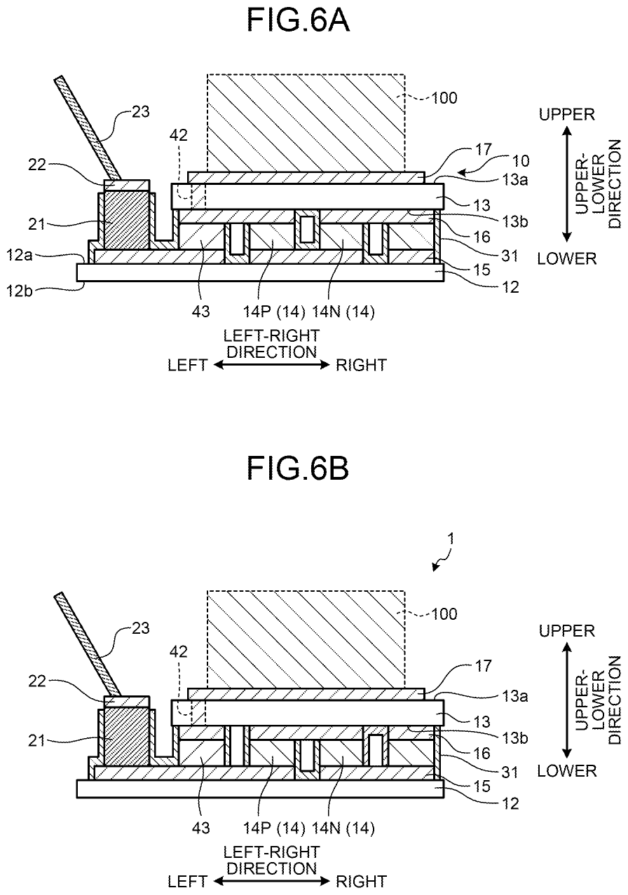

FIG. 6A is a sectional view schematically illustrating a modification of the thermoelectric module according to the first embodiment.

FIG. 6B is a sectional view schematically illustrating a modification of the thermoelectric module according to the first embodiment.

A thermoelectric module 10 includes a through hole 42 and a conductive member 43 as a conductor structure. The through hole 42 is configured in the same manner as in the second modification. The conductive member 43 substitutes for at least one of the thermoelectric conversion elements 14 in the first embodiment. The conductive member 43 is formed, for example, using Au, Ag, Pt, Pd, Cu, Ti, W, Ni, BiTe, or a combination thereof.

In the example illustrated in FIG. 6A, the conductive material 43 and a thermoelectric conversion element 14 are connected in series. In the example illustrated in FIG. 6B, the conductive material 43 and a thermoelectric conversion element 14 are not connected in series.

In a modification, under a condensation condition of a second substrate 13, the thermoelectric module 10 can make a current flow through the through hole 42 and the conductive member 43 from a metallized portion 17 to a first electrode 15 via a second electrode 16. In a modification, even under a condensation condition of the second substrate 13, the thermoelectric module 10 can prevent, by the through hole 42 and the conductive member 43, generation of a potential in the metallized portion 17. According to a modification, even under a condensation condition of the second substrate 13, the thermoelectric module 10 can prevent, by the through hole 42 and the conductive member 43, a current from flowing through the metallized portion 17 via water. According to such a modification, electrochemical migration in the metallized portion 17 can be prevented by the through hole 42 and the conductive member 43.

### Third Modification of First Embodiment

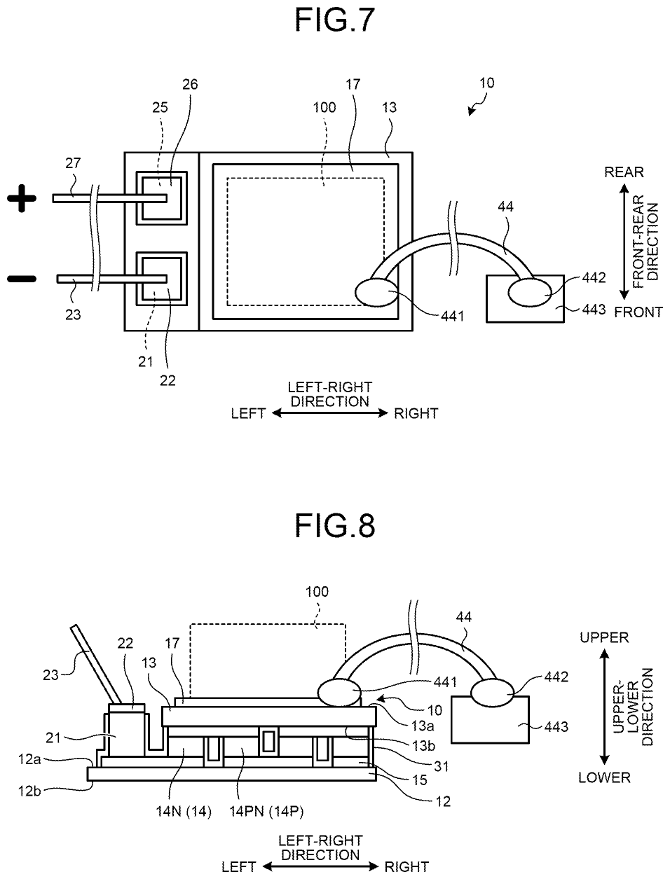

FIG. 7 is a plan view schematically illustrating a modification of the thermoelectric module according to the first embodiment.

FIG. 8 is a sectional view schematically illustrating a modification of the thermoelectric module according to the first embodiment. A thermoelectric module 10 includes a conductive wire 44 as a conductor structure. The thermoelectric module 10 includes a power cathode 443.

The conductive wire 44 electrically connects a metallized portion 17 and the power cathode 443. The conductive wire 44 is fixed to the metallized portion 17 by a solder 441. The conductive wire 44 is fixed to the power cathode 443 by a solder 442. The conductive wire 44 is formed, for example, using Cu, Ni, or Au. The conductive wire 44 may be formed, for example, using Ag, Pt, Pd, Ti, W, BiTe, or a combination thereof. The solder 441 and the solder 442 are formed, for example, using AuSn, SnAgCu, SnSb, CuSn, InSn, or BiSn.

In a modification, under a condensation condition of a second substrate 13, the thermoelectric module 10 can make a current flow through the conductive wire 44 from the metallized portion 17 to the power cathode 443. In a modification, even under a condensation condition of the second substrate 13, the thermoelectric module 10 can prevent, by the conductive wire 44, generation of a potential in the metallized portion 17. According to a modification, even under a condensation condition of the second substrate 13, the thermoelectric module 10 can prevent, by the conductive wire 44, a current from flowing through the metallized portion 17 via water. According to such a modification, electrochemical migration in the metallized portion 17 can be prevented by the conductive wire 44.

### Second Embodiment

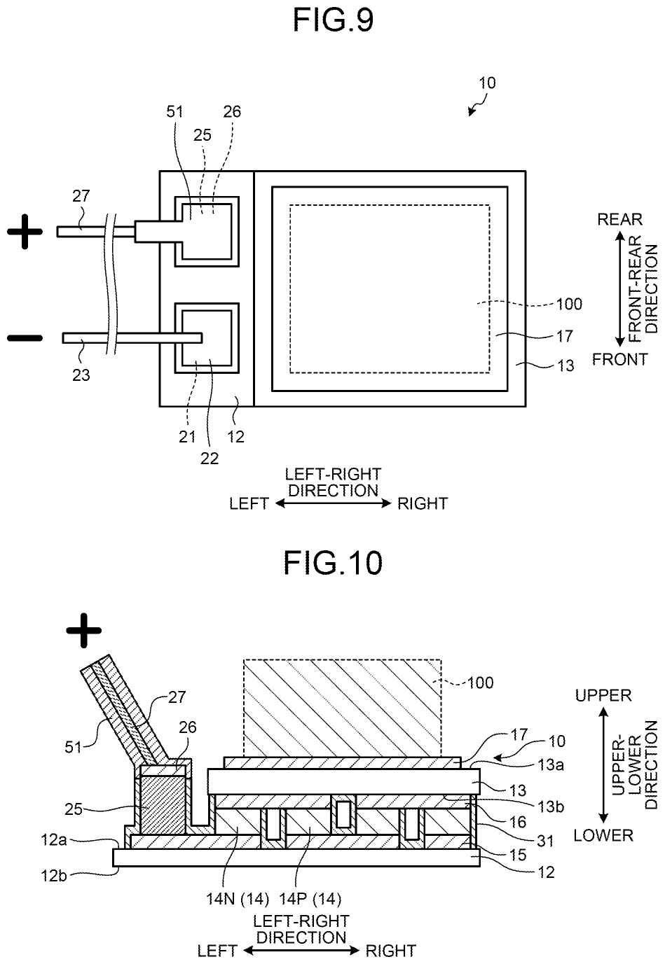

FIG. 9 is a plan view schematically illustrating a thermoelectric module according to a second embodiment.

FIG. 10 is a sectional view schematically illustrating the thermoelectric module according to the second embodiment. A thermoelectric module 10 includes a waterproof member 51.

In an embodiment, the waterproof member 51 is included that separates a post electrode 26 of an anode from a metallized portion 17 disposed on an upper surface 13a of a second substrate 13. More specifically, in the thermoelectric module 10, the metallized portion 17 is not in contact with the post electrode 26 of the anode and a post electrode 22 of a cathode via the waterproof member 51.

The waterproof member 51 is disposed in a state where the metallized portion 17, the post electrode 26 of the anode, and the post electrode 22 of the cathode are separated from each other. In an embodiment, the waterproof member 51 is formed using a material having water resistance. The waterproof member 51 is formed, for example, using an epoxy resin, a polyurethane resin, a silicon resin, an acrylic resin, a fluororesin, a phenol resin, a polyimide resin, or silicon rubber.

The waterproof member 51 is disposed to cover the post electrode 26 of the anode and a power supply wire 27. The waterproof member 51 is positioned to the left of the left end of a first substrate 12 as viewed in the upper-lower direction. The waterproof member 51 is separated from the metallized portion 17 and the post electrode 22 of the cathode. The waterproof member 51 is away from the metallized portion 17 and the post electrode 22 of the cathode.

### Operation

According to an embodiment, even under a condensation condition of the second substrate 13, the thermoelectric module 10 prevents, by the waterproof member 51, a current from flowing through the metallized portion 17 via water. Thus, in such an embodiment, electrochemical migration in the metallized portion 17 is prevented by the wire 41.

In an embodiment, the metallized portion 17 is not in contact with the post electrode 26 of the anode via the waterproof member 51. According to an embodiment, no heat inflow occurs to the metallized portion 17 via the waterproof member 51 to cause no deterioration of the cooling performance.

### Effect

According to an embodiment, even under a condensation condition of the second substrate 13, the thermoelectric module 10 can prevent, by the waterproof member 51, a current from flowing through the metallized portion 17 via water. In an embodiment, even under a condensation condition of the second substrate 13, the thermoelectric module 10 can prevent, by the waterproof member 51, generation of a potential in the metallized portion 17. Thus, in such an embodiment, electrochemical migration in the metallized portion 17 can be prevented by the waterproof member 51.

In an embodiment, the metallized portion 17 is not in contact with the post electrode 26 of the anode via the waterproof member 51. According to an embodiment, no heat inflow occurs to the metallized portion 17 via the waterproof member 51, and deterioration of the cooling performance can be suppressed.

### First Modification of Second Embodiment

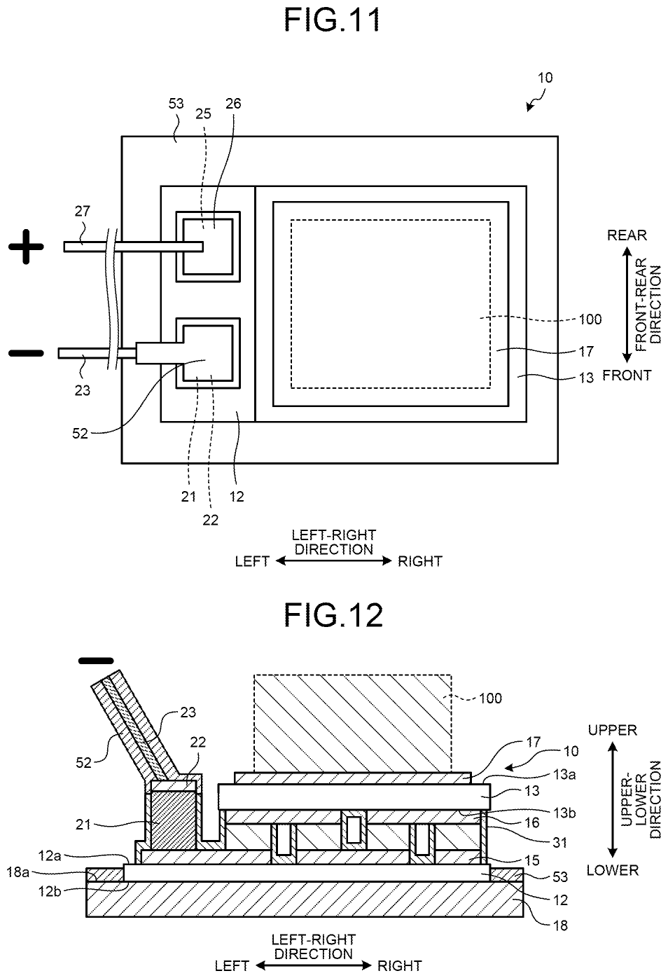

FIG. 11 is a plan view schematically illustrating a modification of the thermoelectric module according to the second embodiment.

FIG. 12 is a sectional view schematically illustrating a modification of the thermoelectric module according to the second embodiment.

In a thermoelectric module 10 in the first modification, a metallized portion 17 is not in contact with a post electrode 26 of an anode, a post electrode 22 of a cathode, and a housing 18 via a waterproof member 52 and a waterproof member 53.

The thermoelectric module 10 includes the housing 18. The housing 18 is joined to a lower surface 12b of a first substrate 12. In the housing 18 in FIG. 12, only a wall joined to the lower surface 12b of the first substrate 12 is illustrated, and other walls are not illustrated. The housing 18 houses the thermoelectric module 10 and an optical component 100. The housing 18 is grounded.

The thermoelectric module 10 includes the waterproof member 52 and the waterproof member 53. The waterproof member 52 and the waterproof member 53 are formed using a material similar to that of the waterproof member 51.

The waterproof member 52 is disposed to cover the post electrode 22 of the cathode and a power supply wire 23. The waterproof member 52 is positioned to the left of the left end of the first substrate 12 as viewed in the upper-lower direction. The waterproof member 52 is separated from the metallized portion 17 and the post electrode 26 of the anode. The waterproof member 52 is away from the metallized portion 17 and the post electrode 26 of the anode.

The waterproof member 53 is disposed to cover an exposed part in a surface 18a, which is in contact with the lower surface 12b of the first substrate 12, of the housing 18. The waterproof member 53 is separated from the metallized portion 17, the post electrode 22 of the cathode, and the post electrode 26 of the anode. The waterproof member 53 is away from the metallized portion 17, the post electrode 22 of the cathode, and the post electrode 26 of the anode.

The thermoelectric module 10 includes the waterproof member 52 that separates the post electrode 22 of the cathode from the metallized portion 17 disposed on an upper surface 13a of a second substrate 13, and the waterproof member 53 that separates the housing 18 that is grounded from the metallized portion 17. More specifically, in the thermoelectric module 10, the metallized portion 17 is not in contact with the post electrode 22 of the cathode and the housing 18 via the waterproof member 51.

According to a modification, even under a condensation condition of the second substrate 13, the thermoelectric module 10 can prevent, by the waterproof member 52 and the waterproof member 53, a current from flowing through the metallized portion 17 via water. In a modification, even under a condensation condition of the second substrate 13, the thermoelectric module 10 can prevent, by the waterproof member 52 and the waterproof member 53, generation of a potential in the metallized portion 17. Thus, in such a modification, electrochemical migration in the metallized portion 17 can be prevented by the waterproof member 52 and the waterproof member 53.

In a modification, the metallized portion 17 is not in contact with the post electrode 22 of the cathode and the housing 18 via the waterproof member 52 and the waterproof member 53. According to a modification, no heat inflow occurs to the metallized portion 17 via the waterproof member 52 and the waterproof member 53, and deterioration of the cooling performance can be suppressed.

### Second Modification of Second Embodiment

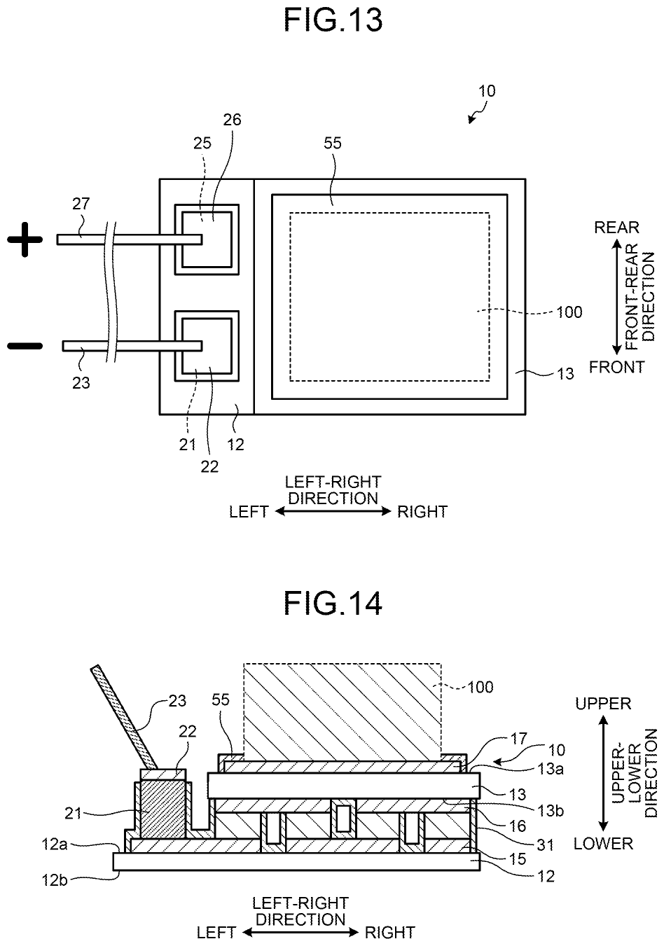

FIG. 13 is a plan view schematically illustrating a modification of the thermoelectric module according to the second embodiment.

FIG. 14 is a sectional view schematically illustrating a modification of the thermoelectric module according to the second embodiment.

In the second modification, a waterproof member 55 is included that separates a post electrode 26 of an anode from a metallized portion 17 disposed on an upper surface 13a of a second substrate 13. More specifically, in a thermoelectric module 10, the metallized portion 17 is not in contact with the post electrode 26 of the anode and a post electrode 22 of a cathode via the waterproof member 55.

The thermoelectric module 10 includes the waterproof member 55. The waterproof member 55 is disposed to cover an exposed part of the metallized portion 17 on which an optical component 100 is installed. The waterproof member 55 is formed using a material similar to that of the waterproof member 51. The waterproof member 55 is separated from the post electrode 22 of the cathode and the post electrode 26 of the anode. The waterproof member 55 is away from the post electrode 22 of the cathode and the post electrode 26 of the anode.

The thermoelectric module 10 includes the waterproof member 55 that separates the exposed part of the metallized portion 17 on which the optical component 100 is installed from the post electrode 22 of the cathode and the post electrode 26 of the anode. More specifically, in the thermoelectric module 10, the metallized portion 17 is not in contact with the post electrode 22 of the cathode and the post electrode 26 of the anode.

According to a modification, even under a condensation condition of the second substrate 13, the thermoelectric module 10 can prevent, by the waterproof member 55, a current from flowing through the metallized portion 17 via water. In a modification, even under a condensation condition of the second substrate 13, the thermoelectric module 10 can prevent, by the waterproof member 55, generation of a potential in the metallized portion 17. Thus, in such a modification, electrochemical migration in the metallized portion 17 can be prevented by the waterproof member 55.

### Third Modification of Second Embodiment

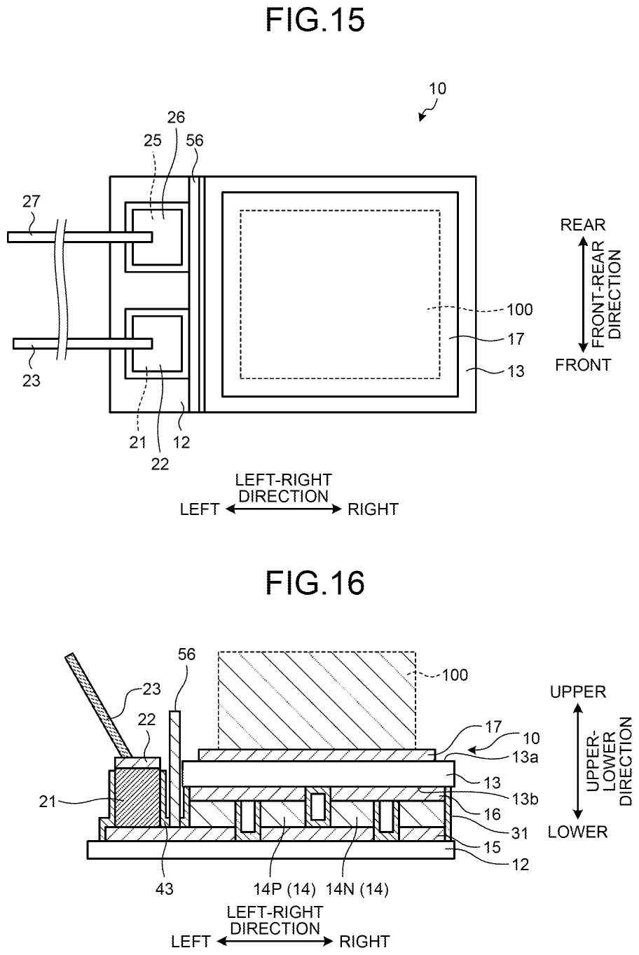

FIG. 15 is a plan view schematically illustrating a modification of the thermoelectric module according to the second embodiment.

FIG. 16 is a sectional view schematically illustrating a modification of the thermoelectric module according to the second embodiment.

In the third modification, a protrusion 56 is provided between a metallized portion disposed on an upper surface 13a of a second substrate 13 and a post electrode 26 of an anode. In other words, a protrusion 56 is included that separates a post electrode 22 of a cathode and the post electrode 26 of the anode from a metallized portion 17 disposed on the upper surface 13a of the second substrate 13. The protrusion 56 separates the metallized portion 17 from electrically uninsulated exposed portions of a power supply wire 23 and a power supply wire 27. The metallized portion 17 is not in contact with the post electrode 26 of the anode and the post electrode 22 of the cathode due to the protrusion 56.

The protrusion 56 is formed into a wall shape. The protrusion 56 is arranged in a standing condition upward from a first electrode 15. The protrusion 56 is disposed between posts 21 and 25 and the second substrate 13 in the left-right direction. The upper end of the protrusion 56 in the upper-lower direction is positioned above the metallized portion 17. The protrusion 56 has the same length as a first substrate 12 in the front-rear direction.

The protrusion 56 includes an electrically insulating material such as an epoxy resin, a polyurethane resin, a silicon resin, an acrylic resin, a fluororesin, a phenol resin, a polyimide resin, silicon rubber, polyparaxylylene, or polytetrafluoroethylene.

The protrusion 56 may include a metal material such as Cu, Ni, Pd, Au, Ag, Ti, or W. In a case where the protrusion 56 includes a metal material, the protrusion 56 needs to be electrically disconnected from the post electrode 26 of the anode and the post electrode 22 of the cathode.

According to a modification, even under a condensation condition of the second substrate 13, the thermoelectric module 10 can prevent, by the protrusion 56, a current from flowing through the metallized portion 17 via water. In a modification, even under a condensation condition of the second substrate 13, the thermoelectric module 10 can prevent, by the protrusion 56, generation of a potential in the metallized portion 17. Thus, in such a modification, electrochemical migration in the metallized portion 17 can be prevented by the protrusion 56.

### Third Embodiment

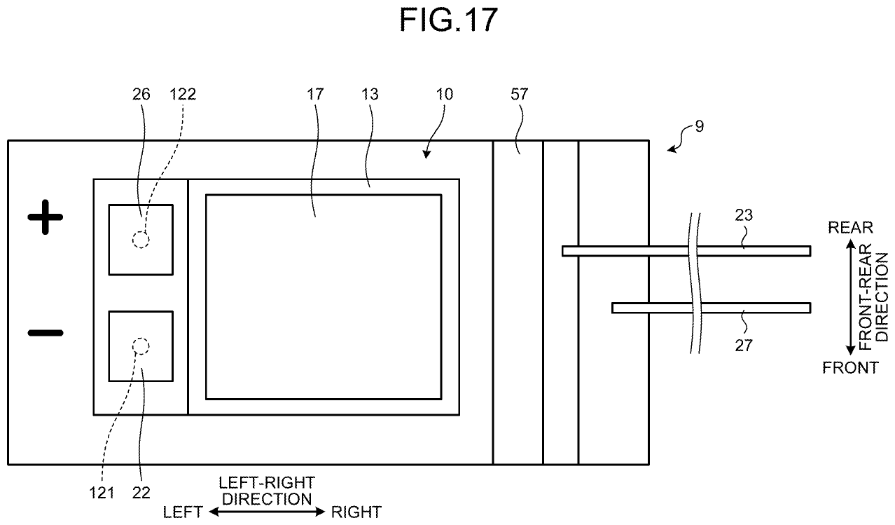

FIG. 17 is a plan view schematically illustrating a thermoelectric module installed on a housing, according to a third embodiment.

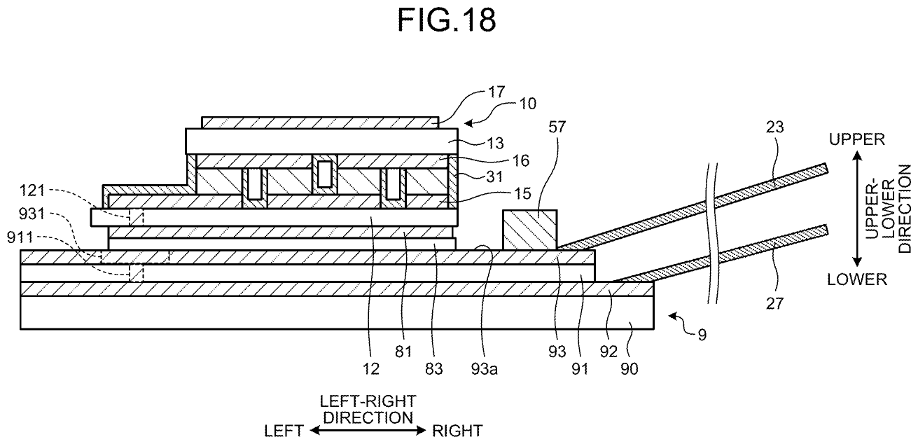

FIG. 18 is a sectional view schematically illustrating the thermoelectric module installed on a housing, according to the third embodiment.

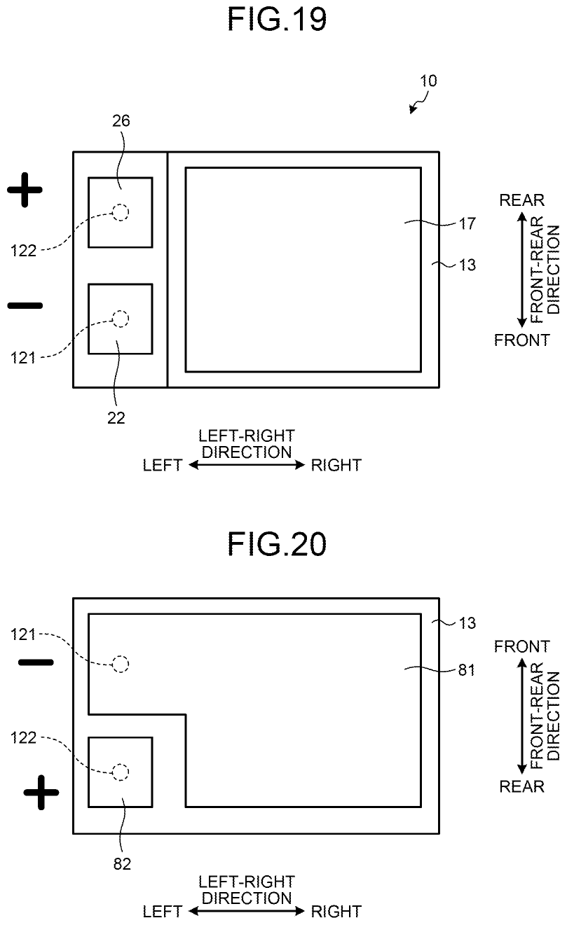

FIG. 19 is a plan view schematically illustrating the upper surface of the thermoelectric module according to the third embodiment.

FIG. 20 is a plan view schematically illustrating the lower surface of the thermoelectric module according to the third embodiment.

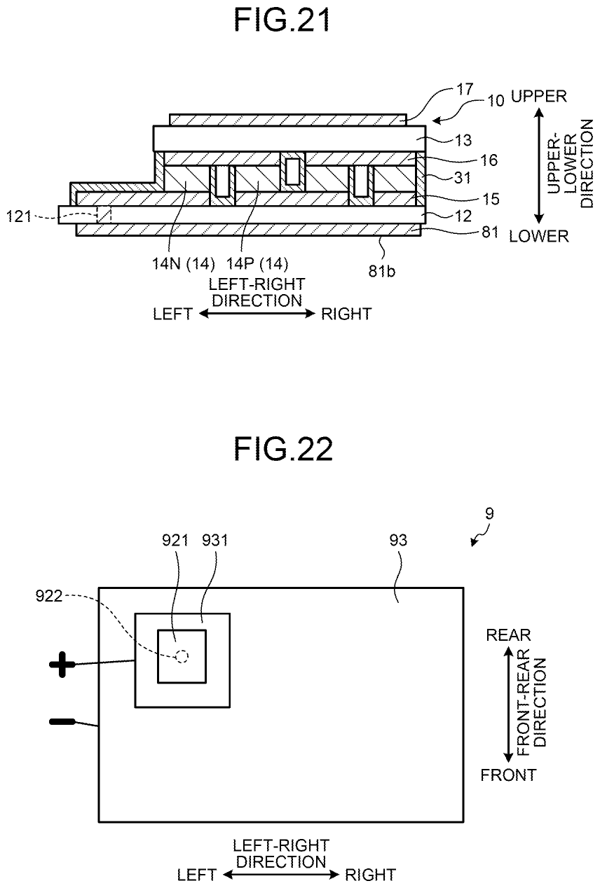

FIG. 21 is a sectional view schematically illustrating the thermoelectric module according to the third embodiment.

FIG. 22 is a plan view schematically illustrating the housing according to the third embodiment.

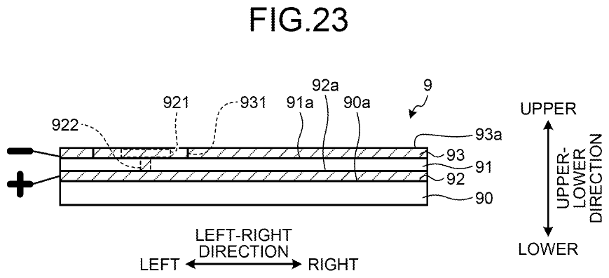

FIG. 23 is a sectional view schematically illustrating the housing according to the third embodiment.

FIG. 17 and FIG. 18 illustrate a thermoelectric module 10 that is installed on a housing with a circuit (hereinafter, referred to as “housing”) 9. The thermoelectric module 10 is disposed on an upper surface 93a of the housing 9. The housing 9 is obtained by adding an electronic circuit to a housing that is to house the thermoelectric module 10 and an optical component 100. In the housing 9 in FIG. 18, only a wall joined to a lower surface 12b of a first substrate 12 is illustrated, and other walls are not illustrated. The housing 9 includes an electronic circuit to be electrically connected to the thermoelectric module 10.

The housing 9 on which a pair of the first substrate 12 and a second substrate 13 of thermoelectric module 10 are mounted includes an electric circuit. The first substrate 12 includes a through hole 121. A first electrode 15 and a second electrode 16 are electrically connected to a post electrode 26 of an anode and a post electrode 22 of a cathode via the through hole 121 and the electric circuit. A protrusion 57 is provided on the upper surface of the housing 9.

The thermoelectric module 10 includes a metallized portion 81 and a metallized portion 82 on the lower surface 12b of the first substrate 12. The metallized portion 81 is electrically connected to the first electrode 15 via the through hole 121. The metallized portion 81 is formed using a conductive metal. The through hole 121 is disposed at a position overlapping the post electrode 22 as viewed in the upper-lower direction. The metallized portion 82 is electrically connected to the first electrode 15 via a through hole 122. The metallized portion 82 is formed using a conductive metal. The through hole 122 is disposed at a position overlapping the post electrode 26 as viewed in the upper-lower direction.

The housing 9 includes a housing substrate 90, a housing first electrode 92 layered on an upper surface 90a of the housing substrate 90, an insulating layer 91 layered on an upper surface 92a of the housing first electrode 92, and a housing second electrode 93 layered on an upper surface 91a of the insulating layer 91.

The housing substrate 90 is formed using an electrically insulating material. The housing substrate 90 is formed into a plate shape. In an embodiment, the housing substrate 90 is formed into a rectangular shape.

In the housing first electrode 92 in a state of being assembled with the thermoelectric module 10, an electrode 921 is disposed at a position overlapping the post electrode 26 as viewed in the upper-lower direction. The electrode 921 is disposed at the same height in the upper-lower direction as the housing second electrode 93 in side view. The electrode 921 is connected to the housing first electrode 92 via a through hole 922. The electrode 921 is connected to the metallized portion 82 of the thermoelectric module 10.

In the housing second electrode 93 in a state of being assembled with the thermoelectric module 10, an opening 931 is formed at a position overlapping the post electrode 26 as viewed in the upper-lower direction. The opening 931 is formed into a size and a shape such that the entire circumference of the electrode 921 is exposed.

The thermoelectric module 10 and the housing 9 are jointed to each other via a joint layer 83. The joint layer 83 is, for example, an adhesive having conductivity. The joint layer 83 is, for example, a resin such as epoxy, phenol, acrylic, urethane, or silicon, or a conductive filler such as Au, Ag, Cu, Ni, or C.

### Effect

According to such an embodiment, electrochemical migration in the metallized portion 17 can be prevented. According to an embodiment, deterioration of cooling performance can be suppressed, and electrochemical migration can be suppressed.

According to the present disclosure, deterioration of cooling performance can be suppressed, and electrochemical migration can be suppressed.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A thermoelectric module to be used for optical communication, the thermoelectric module comprising:
a pair of substrates disposed opposite to each other;
a plurality of thermoelectric elements disposed between the pair of substrates;
a pair of electrodes connecting the plurality of thermoelectric elements;
a metallized portion disposed on one substrate of the pair of substrates;
an anode electrode electrically connected to the pair of electrodes;
a cathode electrode electrically connected to the pair of electrodes; and
a conductor structure electrically connecting the metallized portion and a part having a lower voltage than the anode electrode.

2. The thermoelectric module according to claim 1,
wherein
the conductor structure is a wire electrically connecting the metallized portion and the cathode electrode.

3. The thermoelectric module according to claim 1, wherein
the conductor structure is a through hole electrically connecting the metallized portion and one electrode of the pair of electrodes.

4. The thermoelectric module according to claim 1, wherein
the conductor structure is a through hole and a conductive member that electrically connect the metallized portion and one electrode of the pair of electrodes.

5. The thermoelectric module according to claim 4, wherein
the conductive member is not connected in series to the plurality of thermoelectric elements.

6. The thermoelectric module according to claim 1, comprising
a power cathode, wherein
the conductor structure is a conductive wire electrically connecting the metallized portion and the power cathode.

7. A thermoelectric module to be used for optical communication, the thermoelectric module comprising:
a pair of substrates disposed opposite to each other;
a plurality of thermoelectric elements disposed between the pair of substrates;
a pair of electrodes connecting the plurality of thermoelectric elements;
a metallized portion disposed on one substrate of the pair of substrates;
an anode electrode electrically connected to the pair of electrodes;
a cathode electrode electrically connected to the pair of electrodes; and
a waterproof member disposed in a state where the metallized portion, the anode electrode, and the cathode electrode are separated from each other.

8. The thermoelectric module according to claim 7, wherein
the waterproof member is disposed to cover the anode electrode.

9. The thermoelectric module according to claim 7, comprising
a housing disposed on another substrate of the pair of substrates, wherein
the waterproof member is disposed to cover the cathode electrode and an exposed part of the housing.

10. The thermoelectric module according to claim 7, wherein
the waterproof member is disposed to cover an exposed part of the metallized portion.

11. The thermoelectric module according to claim 7, comprising
a protrusion disposed between the metallized portion and the anode electrode.

12. The thermoelectric module according to claim 7, wherein
the housing on which the pair of substrates are mounted includes an electric circuit,
a substrate positioned lower of the pair of substrates includes a through hole,
the pair of electrodes are connected to the anode electrode and the cathode electrode via the through hole and the electric circuit, and
the housing has an upper surface provided with a protrusion.
